(19) United States
(12) Patent Application Publication
(10) Pub. No.: US 2010/0238711 A1
(43) Pub. Date: Sep. 23, 2010

(54) RESISTANCE-CHANGE MEMORY

(75) Inventor: Yoshiaki ASAO, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/726,203

(22) Filed: Mar. 17, 2010

(30) Foreign Application Priority Data
Mar. 23, 2009 (JP) 2009-070583

(51) Int. Cl. G11C 11/00

(52) U.S. Cl. 365/148

(57) ABSTRACT

A resistance-change memory of an aspect of the present invention including a first bit line, second and third bit lines extending in a direction intersecting with the first bit line, first and second word lines, a first select transistor in which a control terminal thereof is connected to the first word line and in which one end of a current path thereof is connected to the second bit line, a second select transistor in which a control terminal thereof is connected to the second word line and in which one end of a current path thereof is connected to the third bit line and in which the end of a current path thereof forms a node together with the other end of the first select transistor, and a resistance-change storage element which has one end connected to the first bit line and the other end connected to the node.

### CROSS-REFERENCE TO RELATED APPLICATIONS

This application is based upon and claims the benefit of priority from prior Japanese Patent Application No. 2009-070583, filed Mar. 23, 2009, the entire contents of which are incorporated herein by reference.

### BACKGROUND OF THE INVENTION

1. Field of the Invention

The present invention relates to a resistance-change memory using a resistance-change storage element for a memory cell.

2. Description of the Related Art

Recently, semiconductor memories that use a resistance-change storage element as a storage element, such as a phase-change random access memory (PCRAM) or a magnetic random access memory (MRAM), have been attracting attention and are being developed.

The MRAM is a device that uses the magnetoresistive effect to storage binary 1 or 0 in a memory cell to thereby implement a memory function. The MRAM has the combined merits of nonvolatility, high-speed operation, high integration and high reliability, and is therefore ranked as a candidate memory device to replace the SRAM, pseudo-SRAM (PSRAM) and DRAM.

There have been reported many MRAMs using magnetoresistive elements that exhibit the tunneling magnetoresistive (TMR) effect. In general use as a TMR effect element is a magnetic tunnel junction (MTJ) element which has a stack structure consisting of two ferromagnetic layers with a nonmagnetic layer interposed therebetween and which utilizes the change of magnetic resistance caused by a spin-polarized tunneling effect. The MTJ element can adopt a low- or a high-resistance state depending on the magnetization arrangement of the two ferromagnetic layers. The low-resistance state is defined as binary 0; the high-resistance state, as binary 1. Thus one-bit data can be recorded in the MTJ element.

To write to the MRAM, a write current, for example, is passed through the MTJ element, and the magnetization arrangement of the MTJ element is changed from a parallel state to an antiparallel state or from an antiparallel state to a parallel state depending on the direction of the write current.

For example, in the connection relation of a general 1Tr+1MTJ memory cell, one end of the MTJ element is connected to a first bit line, the other end of the MTJ element is connected to one source/drain region of a select transistor, and the other source/drain region of the select transistor is connected to a second bit line. The first bit line and the second bit line extend in the same direction, and are formed of different metal interconnect layers. Therefore, the manufacturing process and manufacturing costs of the MRAM are increased.

Furthermore, in the 1Tr+1MTJ memory cell, to supply the write current to the MTJ element, the write current is supplied to the MTJ element via one select transistor. Thus, the write current is limited by the gate breakdown voltage of the select transistor and by a source-drain breakdown voltage, and there may be cases where a current high enough to change the magnetization arrangement of the MTJ element can not be ensured.

In addition, Jpn. Pat. Appln. KOKAI Publication No. 2008-147515 discloses a 2Tr+2MTJ memory cell wherein two bit lines forming a bit line pair extend in directions intersecting with each other, and two select transistors are provided for two TMR effect elements.

### BRIEF SUMMARY OF THE INVENTION

A resistance-change memory of an aspect of the present invention comprising: a first bit line extending in a first direction; second and third bit lines extending in a second direction intersecting with the first direction; first and second word lines extending in the second direction; a first select transistor in which a control terminal thereof is connected to the first word line and in which one end of a current path thereof is connected to the second bit line; a second select transistor in which a control terminal thereof is connected to the second word line, in which one end of a current path thereof is connected to the third bit line and in which the other end of the current path thereof forms a common node together with the other end of the current path of the first select transistor; and a resistance-change storage element which has one end connected to the first bit line and the other end connected to the common node and which changes in resistance in accordance with data to be stored.

A resistance-change memory of an aspect of the present invention comprising: a first bit line provided above a substrate and extending in a first direction; a first select transistor which includes a first source/drain region as a second bit line provided in the substrate and extending in a second direction intersecting with the first direction, a second source/drain region provided in the substrate, and a first gate electrode as a first word line provided on the substrate between the first and second source/drain regions via a gate insulating film; a second select transistor which includes the second source/drain region shared with the first select transistor, a third source/drain region as a third bit line provided in the substrate and extending in the second direction, and a second gate electrode as a second word line provided on the substrate between the second and third source/drain regions via a gate insulating film; and a first resistance-change storage element which includes a first terminal connected to the first bit line and a second terminal connected to the second source/drain region and which is disposed under the first bit line, the first resistance-change storage element reversibly changing in resistance in accordance with data to be stored.

A resistance-change memory of an aspect of the present invention comprising: a first bit line provided above a substrate and extending in a first direction; an active region which is provided in a memory cell array in the substrate, which extends from one end of the memory cell array to the other end thereof in the first direction, and which is interposed between two element isolation insulating films provided in the substrate in a second direction intersecting with the first direction; a first select transistor which includes a first source/drain region provided in the active region, a second source/drain region provided in the active region, and a first gate electrode provided on the substrate between the first and second source/drain regions via a gate insulating film; a second select transistor which includes the second source/drain region shared with the first select transistor, a third source/drain region provided in the active region, and a second gate electrode provided on the substrate between the second and third source/drain regions via a gate insulating film; a resistance-change storage element which includes one end connected to the first bit line and the other end connected to the second source/drain region and which is disposed under the first bit line, the resistance-change storage element reversibly changing in resistance in accordance with data to be stored; a second bit line which is disposed between the first bit line and the first source/drain region and which is connected to the first source/drain region and which extends in a second direction intersecting with the first direction; and a third bit line which is disposed between the first bit line and the third source/drain region and which is connected to the third source/drain region and which extends in the second direction.

### BRIEF DESCRIPTION OF THE SEVERAL VIEWS OF THE DRAWING

FIG. 1 is an equivalent circuit diagram of a memory cell of a resistance-change memory according to an embodiment;

FIG. 2 is a plan view of the memory cell of the resistance-change memory according to the present embodiment;

FIG. 3 is a sectional view taken along line III-III of FIG. 2;

FIG. 4 is a sectional view taken along line IV-IV of FIG. 2;

FIG. 5 is a sectional view showing an example of the configuration of a resistance-change storage element;

FIG. 6 is an equivalent circuit diagram of a memory cell array of the resistance-change memory according to the present embodiment;

FIG. 7 is a plan view of the memory cell array of the resistance-change memory according to the present embodiment;

FIG. 8 is a sectional view taken along line A-A′ of FIG. 7;

FIG. 9 is a sectional view taken along line B-B′ of FIG. 7;

FIG. 10 is a waveform chart for explaining the operation of the resistance-change memory according to the present embodiment;

FIG. 11 is a waveform chart for explaining the operation of the resistance-change memory according to the present embodiment;

FIG. 12 is a waveform chart for explaining the operation of the resistance-change memory according to the present embodiment;

FIG. 13 is a plan view for explaining an example of the memory cell array shown in FIG. 7;

FIG. 14A is a sectional view taken along line C-C′ of FIG. 13;

FIG. 14B is a sectional view taken along line D-D′ of FIG. 13;

FIG. 15 is a waveform chart for explaining the operation of the resistance-change memory according to the present embodiment;

FIG. 16 is a plan view for explaining a modification of the memory cell array shown in FIG. 7;

FIG. 17 is a sectional view taken along line E-E′ of FIG. 16;

FIG. 18 is a sectional view taken along line F-F′ of FIG. 16;

FIG. 19 is a sectional view showing an example of the configuration of the resistance-change storage element; and

FIG. 20 is a sectional view showing an example of the configuration of the resistance-change storage element.

### DETAILED DESCRIPTION OF THE INVENTION

Hereinafter, an embodiment of the present invention will be described in detail with reference to the drawings. In the following explanation, elements having the same function and configuration are provided with the same signs and are repeatedly described only when necessary.

There are various resistance-change memories such as a magnetic random access memory (MRAM), a resistance random access memory (ReRAM) and a phase-change random access memory (PCRAM).

The MRAM is mainly described as an example in the present embodiment.

### EMBODIMENT

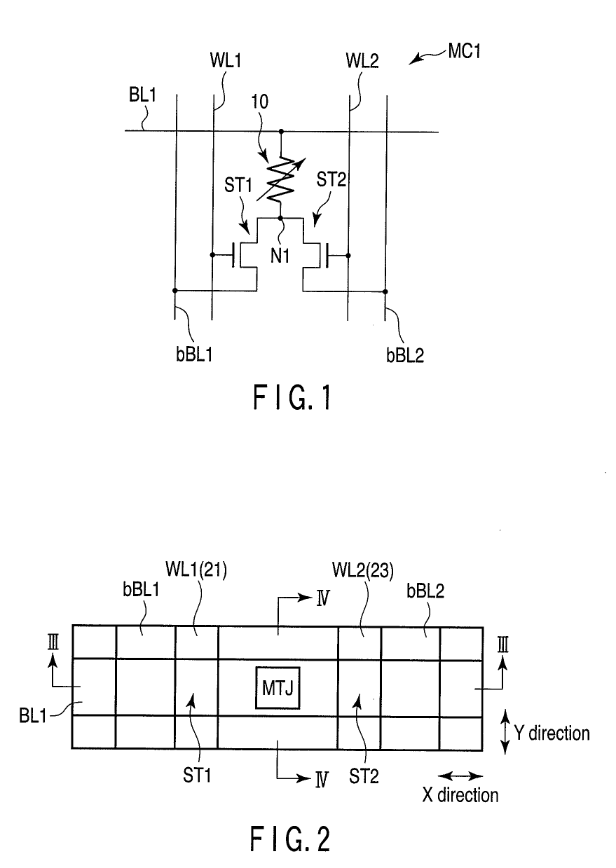

A resistance-change memory according to the embodiment of the present invention is described below with reference to FIGS. 1 to 20.

### (1) Memory Cell

The resistance-change memory (MRAM) according to the present embodiment is described with FIGS. 1 to 4.

FIG. 1 shows an equivalent circuit diagram of a memory cell for constituting the memory according to the present embodiment.

A memory cell MC1 shown in FIG. 1 has, as constituent elements, one resistance-change storage element 10 and two select transistors ST1, ST2.

Select transistors ST1, ST2 are, for example, field effect transistors (FET).

The gate of the first select transistor ST1 is electrically connected to a word line WL1. One end of the current path (source/drain) of select transistor ST1 is electrically connected to a bit line (second bit line) bBL1.

The gate of the second select transistor ST2 is electrically connected to a word line WL2. One end of the current path (source/drain) of select transistor ST2 is electrically connected to a bit line (third bit line) bBL2.

The other end of the current path of select transistor ST1 is electrically connected to the other end of the current path of the second select transistor ST2, and this connection point is a common node N1.

The resistance-change storage element 10 is a two-terminal element. One end of the resistance-change storage element 10 is electrically connected to a bit line BL1. The other end of the resistance-change storage element 10 is electrically connected to the common node N1 of the two select transistors ST1, ST2.

Bit line (first bit line) BL1 extends in, for example, an X direction. Word lines WL1, WL2 extend in a Y direction that intersects with the X direction.

Bit lines that make bit line pairs with bit line BL1 are a bit line bBL1 and a bit line bBL2. The two bit lines bBL1, bBL2 extend in the Y direction, that is, a direction that intersects with bit line BL1.

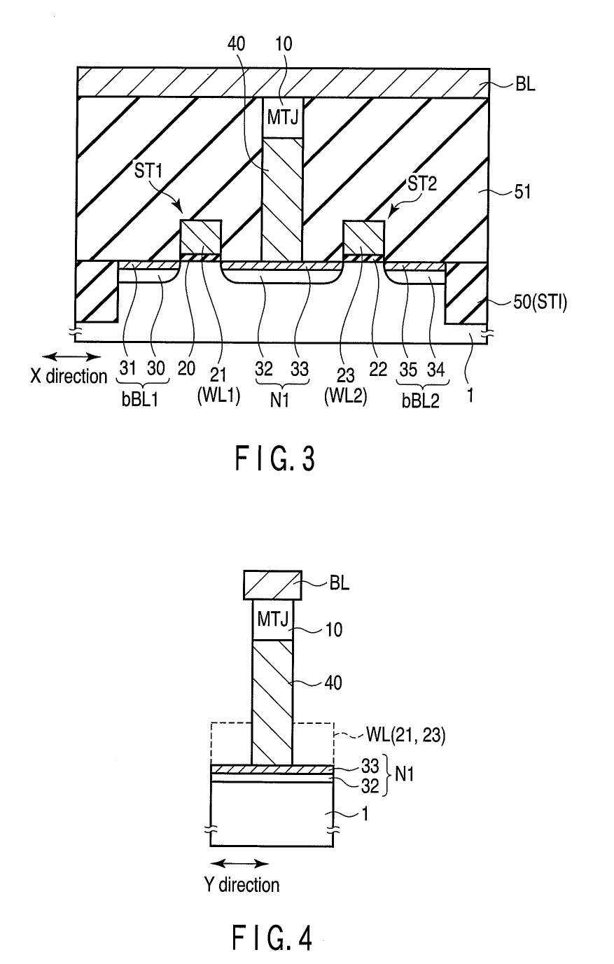

FIGS. 2 to 4 show the structure of the memory cell MC shown in FIG. 1. FIG. 2 shows the planar structure of one memory cell MC. FIG. 3 shows a sectional view taken along line III-III of FIG. 2. FIG. 4 shows a sectional view taken along line IV-IV of FIG. 2. It is to be noted that, in FIG. 4, parts located near or in a depth direction are indicated by broken lines, and some parts are not shown for clarity.

A substrate 1 has an element isolation region in which an element isolation insulating layer 50 is embedded, and an active region (element formation region) made of semiconductor. Constituent elements of the memory cell are formed in the active region.

The two select transistors ST1, ST2 are provided in the active region of the substrate 1.

Two gate electrodes 21, 23 are provided on the substrate (active region) 1 via gate insulating films 20, 22, respectively. The two gate electrodes 21, 23 adjoin each other to leave a predetermined space therebetween. The two gate electrodes 21, 23 extend in the Y direction, and are used as the two word lines WL1, WL2, respectively.

Select transistor ST1 has two source/drain regions 30, 31, 32, 33 in the substrate 1. Select transistor ST2 has two source/drain regions 32, 33, 34, 35 in the substrate 1.

Select transistor ST1 and select transistor ST2 share the source/drain region 32, 33 provided in the substrate 1 between word lines WL1, WL2 (gate electrodes 21, 23). The source/drain region 32, 33 shared by the two select transistors ST1, ST2 serves as the common node N1.

The remaining source/drain regions 30, 31, 34, 35 except for the source/drain region 32, 33 serving as the common node N1 function as bit lines bBL1, bBL2.

That is, the source/drain region 30, 31 of select transistor ST1 is used as bit line bBL1, and extends in the Y direction. The source/drain region 34, 35 of select transistor ST2 is used as bit line bBL2, and extends in the Y direction.

In addition, the source/drain region 32, 33 serving as the common node N1 does not extend in the Y direction, and is electrically isolated in the Y direction by an element isolation insulating layer (not shown).

Each of the source/drain regions is composed of an impurity diffusion layer 30, 32, 34 and a silicide layer 31, 33, 35. The silicide layer 31, 33, 35 is formed on the surface of the impurity diffusion layer 30, 32, 34. The source/drain region may only include the impurity diffusion layer without the silicide layer.

A contact 40 is provided on the source/drain region 32, 33 serving as the common node N1.

The resistance-change storage element 10 is provided on the contact 40. An intermediate layer made of a conductor may be provided between the contact 40 and the resistance-change storage element 10. An interlayer insulating film 51 is provided on the semiconductor substrate 1 to cover select transistors ST1, ST2 and the resistance-change storage element 10.

Bit line BL1 is provided on the resistance-change storage element 10 and on the interlayer insulating film 51 so that bit line BL1 is electrically connected to the resistance-change storage element 10. Bit line BL1 pairs with the two bit lines bBL1, bBL2. In the example shown in FIGS. 3 and 4, bit line BL1 is in direct contact with the resistance-change storage element 10. Bit line BL1 is made of a conductor such as a metal (e.g., aluminum (Al)). In addition, a contact (via plug) or an intermediate layer (e.g., a metal layer) may be provided between bit line BL1 and the resistance-change storage element 10.

Bit line BL1 extends in the X direction. As described above, the two bit lines bBL1, bBL2 constituted of the source/drain regions extend in the Y direction. Thus, in memory cell MC1 of this example, bit line BL1 and bit lines bBL1, bBL2 extend in the directions intersecting with each other. Moreover, word lines WL1, WL2 extend in the direction intersecting with bit line BL1, and extend in the same direction as bit lines bBL1, bBL2.

In addition, as described above, bit lines bBL1, bBL2 are provided in the substrate (active region) 1, and bit line BL1 is provided on the interlayer insulating film 51 higher than bit lines bBL1, bBL2. Hereinafter, for the clarity of explanation, bit line BL1 is referred to as an upper bit line BL1, and bit lines bBL1, bBL2 lower than bit line BL1 are referred to as lower bit lines bBL1, bBL2.

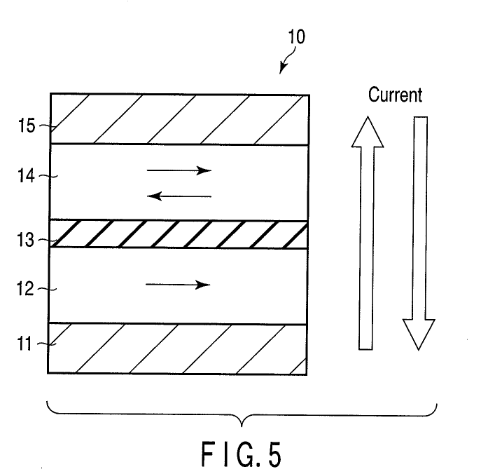

FIG. 5 is a sectional view showing the configuration of one resistance-change storage element 10 included in the MRAM as the resistance-change memory. The MRAM is a memory device that uses the magnetization state of the resistance-change storage element 10 to store information. The resistance-change storage element 10 used for the MRAM is a magnetoresistive effect element 10 that uses a tunneling magnetoresistive (TMR) effect.

The magnetoresistive effect element 10 has a stack structure in which a lower electrode 11, a magnetization reference layer (fixed layer) 12, an intermediate layer (nonmagnetic layer) 13, a magnetization free layer (recording layer) 14 and an upper electrode 15 are stacked in order. The magnetization reference layer 12 and the magnetization free layer 14 may be stacked in reverse order. Thus, the resistance-change storage element 10 used for the MRAM is an element having the stack structure composed of the two ferromagnetic layers 12, 14 and the nonmagnetic layer 13 interposed therebetween, and is a magnetic tunnel junction (MTJ) element that utilizes the change of magnetic resistance caused by a spin-polarized tunneling effect. Hereinafter, the resistance-change storage element 10 is referred to as an MTJ element 10.

The magnetization (or spin) direction of the magnetization free layer 14 is variable (reversible). The magnetization direction of the magnetization reference layer 12 is invariable (fixed). This means that the magnetization direction of the magnetization reference layer 12 does not change when a magnetization inverting current used to invert the magnetization direction of the magnetization free layer 14 is passed through the magnetization reference layer 12. Thus, in the MTJ element 10, a magnetic layer having a high magnetization inverting current (inversion threshold) is used as the magnetization reference layer 12, and a magnetic layer having a magnetization inverting current lower than that of the magnetization reference layer 12 is used as the magnetization free layer 14. This makes it possible to obtain the MTJ element 10 which comprises the magnetization free layer 14 having a variable magnetization direction and the magnetization reference layer 12 having an invariable magnetization direction.

When magnetization is inverted by spin-polarized electrons, a current to cause this inversion is proportional to a damping constant, an anisotropy field and a volume. Therefore, these can be properly adjusted to make a difference of inverting current between the magnetization free layer 14 and the magnetization reference layer 12. Moreover, to fix the magnetization of the magnetization reference layer 12, an antiferromagnetic layer (not shown) may be provided adjacently to the magnetization reference layer 12, so that the magnetization direction of the magnetization reference layer 12 can be fixed by the exchange coupling of the magnetization reference layer 12 and the antiferromagnetic layer.

The easy magnetization direction of the magnetization reference layer 12 and the magnetization free layer 14 may be perpendicular to a film surface (or a stack surface) (hereinafter referred to as perpendicular magnetization) or may be parallel to a film surface (hereinafter referred to as in plane magnetization). A perpendicular magnetization magnetic layer has magnetic anisotropy in a direction perpendicular to the film surface, and an in-plane magnetization magnetic layer has magnetic anisotropy in an in-plane direction. In contrast to the in-plane-magnetization MTJ element, the perpendicular-magnetization MTJ element does not require the control of the shape of the MTJ element to determine the magnetization direction, and is advantageously suited to miniaturization. The planar shape of the MTJ element 10 is not specifically limited, and may be, for example, circular, elliptic, square or rectangular. Moreover, the MTJ element 10 may have a square or rectangular planar shape with rounded or removed corners.

It is preferable that the magnetization reference layer 12 and the magnetization free layer 14 be made of a material having great coercive force, and more specifically, have a high magnetic anisotropy energy density of 1×10⁶ erg/cc or more. The nonmagnetic layer 13 is made of a nonmagnetic material, and more specifically, an insulator, a semiconductor or a metal, for example, can be used for the nonmagnetic layer 13. When the insulator or semiconductor is used for the nonmagnetic layer 13, the nonmagnetic layer 13 is called a tunnel barrier layer.

In addition, each of the magnetization reference layer 12 and the magnetization free layer 14 is not limited to a shown single layer, and may have a stack structure composed of a plurality of ferromagnetic layers. Moreover, each of the magnetization reference layer 12 and the magnetization free layer 14 may be composed of three layers including a first ferromagnetic layer, a nonmagnetic layer and a second ferromagnetic layer, and may have an antiferromagnetically coupled structure in which the first and second ferromagnetic layers are magnetically coupled together (exchange coupling) so that the magnetization directions of these layers may be antiparallel, or may have a ferromagnetically coupled structure in which the first and second ferromagnetic layers are magnetically coupled together (exchange coupling) so that the magnetization directions of these layers may be parallel.

Furthermore, the MTJ element 10 may have a double junction structure. The MTJ element 10 of the double junction structure has a stack structure including a first magnetization reference layer, a first intermediate layer, a magnetization free layer, a second intermediate layer and a second magnetization reference layer that are stacked in order. The advantage of such a double junction structure is that the magnetization inversion of the magnetization free layer by spin transfer is easily controlled.

In the resistance-change memory (e.g., an MRAM) according to the present embodiment, one bit line BL1 and the two bit lines bBL1, bBL2 to pair with bit line BL1 extend in directions intersecting with each other.

Furthermore, one memory cell MC1 used in the resistance-change memory according to the present embodiment includes one resistance-change storage element (e.g., an MTJ element) 10 and two select transistors ST1, ST2.

In the present embodiment, upper bit line BL1 is made of a metal provided on the interlayer insulating film 51. Lower bit lines bBL1, bBL2 to pair with upper bit line BL1 are provided in the substrate 1 and include the source/drain regions of the select transistors.

Thus, in the present embodiment, one bit line bBL1, bBL2 to form a bit line pair is constituted of the impurity diffusion layer and the silicide layer provided in the substrate 1. Thus, there is no need for interconnect layers to provide lower bit lines bBL1, bBL2, and the number of interconnect layers stacked on the substrate 1 can be reduced. As a result, the manufacturing process can be reduced.

Moreover, bit lines bBL1, bBL2 and the source/drain regions of select transistors ST1, ST2 are formed in a common process. Thus, the manufacturing process can be reduced, and there is no need to separately prepare a member to form the lower bit lines.

Therefore, manufacturing costs can be reduced by having a structure in which the interconnect lines BL1, bBL1, bBL2 to form a bit line pair intersect with each other.

Furthermore, in the present embodiment, two select transistors ST1, ST2 are provided for one resistance-change storage element 10.

Thus, the write current can be supplied to the resistance-change storage element (MTJ element) 10 by use of the driving force for the two select transistors ST1, ST2. As a result, a greater write current can be supplied to the resistance-change storage element 10 in the memory cell shown in FIGS. 1 to 4 than in the 1Tr+1MTJ memory cell in which a write current is supplied to the MTJ element by one select transistor.

As described above, according to the resistance-change memory in the embodiment of the present invention, a resistance-change memory with low manufacturing costs and improved operating characteristics can be provided.

### (2) Memory Cell Array

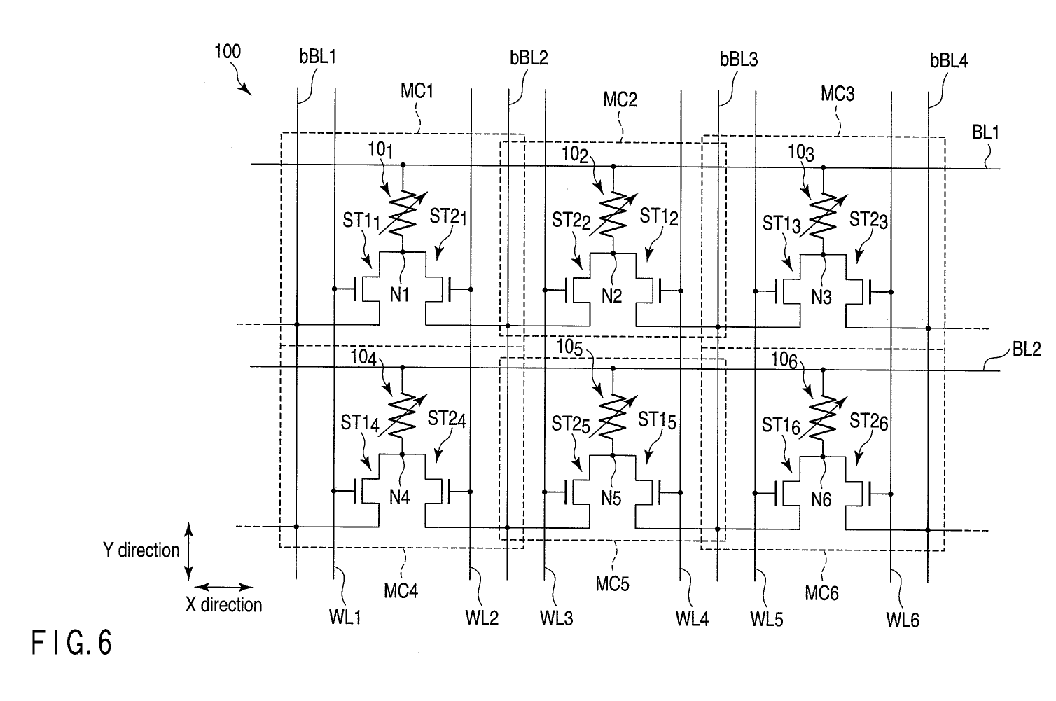

The circuit configuration and structure of the memory cell array that uses the memory cell shown in FIGS. 1 to 4 are described with FIGS. 6 to 9.

(a) Circuit Configuration

FIG. 6 is an equivalent circuit diagram showing the circuit configuration of a memory cell array 100 of the resistance-change memory (MRAM) according to the present embodiment.

In the memory cell array 100, a plurality of memory cells MC1 to MC6 are arranged in a matrix form along the X direction and the Y direction. In the example shown here, six memory cells MC1 to MC6 are used.

A plurality of upper bit lines BL1, BL2 extending in the X direction are provided in the memory cell array 100. Upper bit lines BL1, BL2 are adjacent in the Y direction. In addition, in FIG. 6, two upper bit lines BL1, BL2 are shown by way of example.

Memory cells MC1 to MC6 arranged in the X direction are connected to the common upper bit lines BL1, BL2. In the example shown in FIG. 6, three memory cells MC1 to MC3 arranged along the extending direction (X direction) of upper bit line BL1 are connected to upper bit line BL1. Three memory cells MC4 to MC6 arranged along the extending direction of upper bit line BL2 are connected to upper bit line BL2.

A plurality of lower bit lines bBL1 to bBL4 extending in the Y direction are provided in the memory cell array 100. Lower bit lines bBL1 to bBL4 extend in the direction that intersects with upper bit lines bBL1, bBL2. In FIG. 6, four lower bit lines bBL1 to bBL4 are shown by way of example.

Memory cells MC1 to MC6 arranged in the Y direction are connected to the common Lower bit lines bBL1 to bBL4. For example, lower bit line bBL1 and lower bit line bBL2 are connected to the common memory cell MC1 and memory cell MC4 adjacent to each other in the Y direction. Further, lower bit lines bBL1 to bBL4 are shared by two memory cells MC1 to MC6 adjacent to each other in the X direction. For example, memory cell MC1 and memory cell MC2 adjacent to each other in the X direction are connected to the common lower bit line bBL2. Each of lower bit lines bBL1 to bBL4 pairs with upper bit line BL1 and also pairs with upper bit line BL2.

A plurality of word lines WL1 to WL6 extending in the Y direction are provided in the memory cell array 100. In FIG. 6, six word lines WL1 to WL6 are shown by way of example.

In the present embodiment, each of memory cells MC1 to MC6 comprises one MTJ element 10 and two select transistors ST1, ST2, and is thus a 2Tr+1MTJ memory cell.

Memory cell MC1 comprises an MTJ element 10₁ and two select transistors ST1₁, ST2₁. One end of the MTJ element 10₁ is electrically connected to upper bit line BL1, and the other end of the MTJ element 10₁ is electrically connected to a common node N1 formed by ends of the current paths of the two select transistors ST1₁, ST2₁. The other end of the current path of select transistor ST1₁ is connected to lower bit line bBL1, and the other end of the current path of select transistor ST2₁ is connected to lower bit line bBL2. Moreover, the gate of select transistor ST1₁ is connected to word line WL1, and the gate of select transistor ST2₁ is connected to word line WL2.

Memory cell MC2 comprises an MTJ element 10₂ and two select transistors ST1₂, ST2₂. One end of the MTJ element 10₂ is electrically connected to upper bit line BL1, and the other end of the MTJ element 10₂ is electrically connected to a common node N2 formed by ends of the current paths of the two select transistors ST1₂, ST2₂. The other end of the current path of select transistor ST1₂ is connected to lower bit line bBL3, and the other end of the current path of select transistor ST2₂ is connected to lower bit line bBL2. Two select transistors ST2₁, ST2₂ adjacent in the X direction is connected to the common lower bit line bBL2. Moreover, the gate of select transistor ST2₂ is connected to word line WL3, and the gate of select transistor ST1₂ is connected to word line WL4.

Memory cell MC3 comprises an MTJ element 10₃ and two select transistors ST1₃, ST2₃. One end of the MTJ element 10₃ is electrically connected to upper bit line BL1, and the other end of the MTJ element 10₃ is electrically connected to a common node N3 formed by ends of the current paths of the two select transistors ST1₃, ST2₃. The other end of the current path of select transistor ST1₃ is connected to lower bit line bBL3, and the other end of the current path of select transistor ST2₃ is connected to lower bit line bBL4. Two select transistors ST1₂, ST1₃ adjacent in the X direction is connected to the common lower bit line bBL3. Moreover, the gate of select transistor ST1₃ is connected to word line WL5, and the gate of select transistor ST2₃ is connected to word line WL6.

The configurations of memory cells MC4, MC5, MC6 connected to upper bit line BL2 are repetitions of the configurations of memory cells MC1, MC2, MC3 connected to upper bit line BL1.

In the three memory cells MC4 to MC6 connected to common upper bit line BL2, MTJ element 10₄, 10₅, 10₆ respectively constituting memory cells MC4 to MC6 are connected at one end to upper bit line BL2. The other end of the MTJ element 10₄, 10₅, 10₆ in each of memory cells MC4, MC5, MC6 is connected to a common node N4 to N6 of two select transistors ST1₄, ST1₅, ST1₆, ST2₄, ST2₅, ST2₆ constituting memory cells MC1 to MC6.

Lower bit lines bBL1, bBL2, bBL3, bBL4 are shared by the memory cells adjacent in the Y direction. Therefore, the connection of select transistors ST1₄, ST1₅, ST1₆, ST2₄, ST2₅, ST2₆ to lower bit lines bBL1, bBL2, bBL3, bBL4 is similar to the connection of select transistors ST1₁ to ST1₃, ST2₁ to ST2₃ of memory cells MC1 to MC3 to lower bit lines bBL1, bBL2, bBL3, bBL4.

Moreover, the gates of select transistors ST1₄, ST1₅, ST1₆, ST2₄, ST2₅, ST2₆ are connected to word lines WL1, WL2, WL3, WL4, WL5, WL6, respectively.

(b) Structure

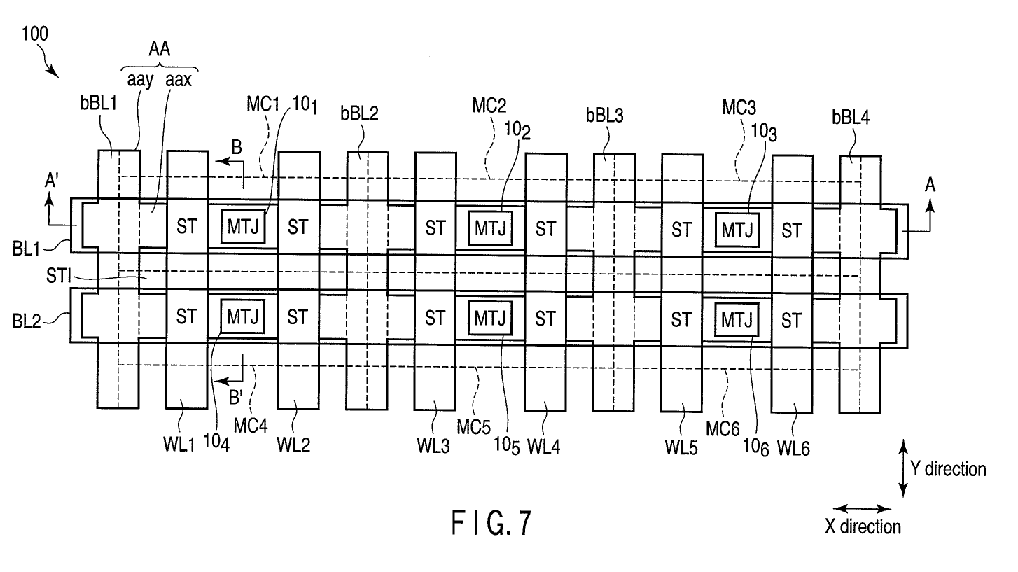

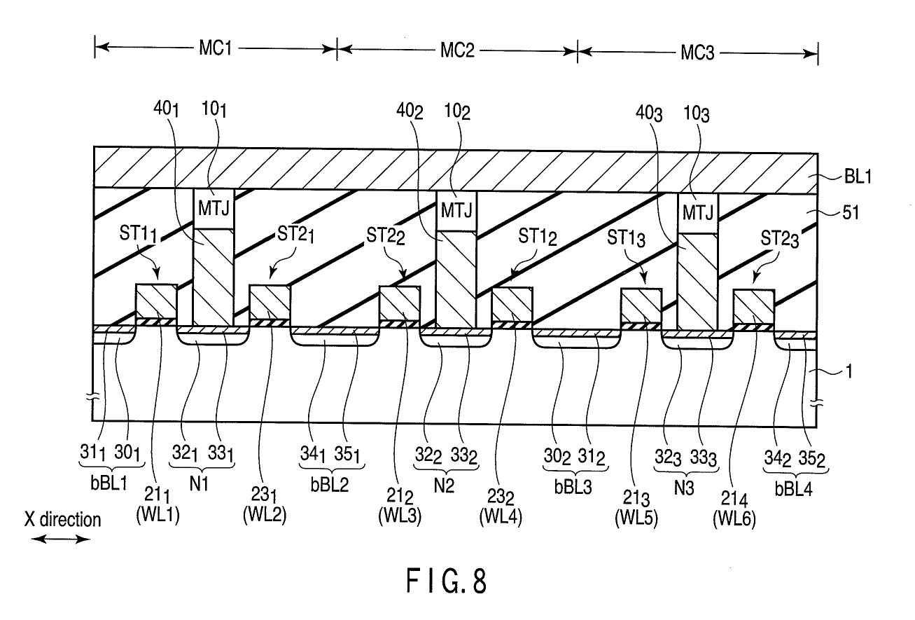

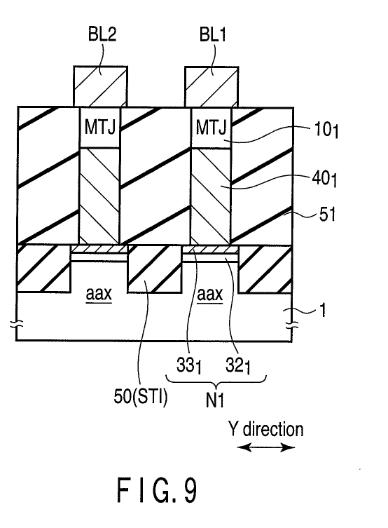

The structure of the memory cell array of the resistance-change memory according to the present embodiment is described with FIGS. 7 to 9. FIG. 7 is a plan view of the memory cell array 100 of the MRAM. FIG. 8 is a sectional view taken along line A-A′ of FIG. 7. FIG. 9 is a sectional view taken along line B-B′ of FIG. 7. It is to be noted that the same components as the components described with FIGS. 2 to 4 are provided with the same reference numbers and are described when necessary.

The substrate 1 is, for example, a P-type semiconductor substrate, a semiconductor substrate having a P-type well, or a silicon-on-insulator (SOI) substrate having a P-type semiconductor layer. For example, a silicon (Si) substrate is used as the semiconductor substrate.

The surface region of the substrate 1 includes an element isolation region STI in which the element isolation insulating layer 50 is embedded, and a semiconductor region (active region) AA in which no insulating layer is formed.

The element isolation insulating layer 50 is configured by, for example, shallow trench isolation (STI). For example, silicon oxide is used for the element isolation insulating layer 50.

The active region AA has a lattice-like planar shape.

A lattice-shaped region aax extending in the X direction is provided under upper bit lines BL1, BL2. The MTJ elements 10₁ to 10₆ and select transistors ST1₁ to ST1₆, ST2₁ to ST2₆ are provided in the region aax.

Lower bit lines bBL1 to bBL4 are provided in a lattice-shaped region aay extending in the Y direction.

Word lines WL1 to WL6 extend in the same direction as lower bit lines bBL1 to bBL4, and intersect with the region aax and the element isolation region STI. Select transistors ST1₁ to ST1₆, ST2₁ to ST2₆ are provided at the position where the semiconductor region aax of the substrate 1 intersects with word lines WL1 to WL6.

For example, such as a layout of two word lines WL1, WL2 and two lower bit lines bBL1, bBL2, two word lines are arranged between two lower bit lines in the X direction.

Each of the MTJ elements 10₁ to 10₆ is disposed between two select transistors ST1₁ to ST1₆, ST2₁ to ST2₆ that constitute one memory cell. The element isolation region STI is provided between the MTJ elements 10₁ to 10₆ adjacent in the Y direction. Two word lines and one lower bit line are disposed between two MTJ elements 10₁ to 10₆ arranged in the X direction.

Each of memory cells MC1 to MC6 has, for example, a quadrangular planar shape.

As shown in FIG. 8, in the active region of the substrate 1, the lattice-shaped regions aax extending in the X direction are not isolated by using insulating films, and are linked to each other via the regions aay. Thus, the active region AA is shared by memory cells MC1 to MC3 adjacent in the X direction. In the present embodiment, memory cells MC1 to MC3 adjacent in the X direction are electrically isolated by controlling the cutoff of select transistors ST1₁ to ST1₃, ST2₁ to ST2₃ and by controlling the potential of the lower bit line.

As described above, memory cell MC1 and memory cell MC2 adjacent to each other in the X direction share one lower bit line bBL2 of two lower bit lines bBL1 to bBL3. Thus, select transistors ST2₁, ST2₂ respectively constituting the different memory cells MC1, MC2 share, as lower bit line bBL2, source/drain regions 34₁, 35₁ on the side where no common node is formed. Similarly, in memory cell MC2 and memory cell MC3, select transistors ST1₂ and select transistors ST1₃ share, as lower bit line bBL3, source/drain regions 30₂, 31₂.

Furthermore, source/drain regions 30₁ to 35₁, 30₂ to 35₂ functioning as lower bit lines bBL1 to bBL4 extend in the Y direction, and are shared by a plurality of memory cells adjacent in the Y direction as the source/drain regions of select transistors ST1₄ to ST1₆, ST2₄ to ST2₆.

The source/drain regions 30₁ to 35₁, 30₂ to 35₂ comprise, for example, impurity diffusion layers 30₁, 32₁, 34₁, 30₂, 32₂, 34₂ and silicide layers 31₁, 33₁, 35₁, 31₂, 33₂, 35₂, 33₃. The silicide layers 31₁, 33₁, 35₁, 31₂, 33₂, 35₂, 33₃ are provided on the impurity diffusion layers 30₁, 32₁, 34₁, 30₂, 32₂, 34₂.

The impurity diffusion layers 30₁, 32₁, 34₁, 30₂, 32₂, 34₂ are, for example, N-type impurity regions. For example, nickel silicide or titanium silicide is used for the silicide layers 31₁, 33₁, 35₁, 31₂, 33₂, 35₂, 33₃. The silicide layers 31₁, 33₁, 35₁, 31₂, 33₂, 35₂, 33₃ are formed simultaneously with the silicide treatment for reducing the resistance of gate electrodes 21₁, 21₂, 21₃, 23₁, 23₂, 23₃ of select transistors ST1, ST2, that is, word lines WL1 to WL6. The silicide layers 31₁, 33₁, 35₁, 31₂, 33₂, 35₂, 33₃ are used for part of the source/drain regions, so that the resistances of lower bit lines bBL1 to bBL4 are lower. At the same time, contact resistance between contacts 40₁, 40₂, 40₃ and the common nodes (source/drain regions) N1 to N3 is reduced. However, the silicide layers may not be formed.

Word lines WL1 to WL6 are provided on the region aax via a gate insulating film. Word lines WL1 to WL6 function as the gate electrodes 21₁ to 21₃, 23₁ to 23₃ of select transistors ST1₁ to ST1₃, ST2₁ to ST2₃. That is, the gate electrodes 21₁ to 21₃, 23₁ to 23₃ of the select transistors extend in the Y direction over the region aax and the element isolation region STI, and are shared by a plurality of select transistors arranged in the Y direction.

The contacts 40₁ to 40₃ are provided on the source/drain regions 32₁, 33₁, 32₂, 33₂, 32₃, 32₃ shared as nodes N1 to N3 by two select transistors. The contacts 40₁ to 40₃ are made of a conductor such as tungsten. The MTJ elements 10₁ to 10₃ are provided on the contacts 40₁ to 40₃.

Upper bit line BL1 extends in the X direction, and is provided on the MTJ elements 10₁ to 10₃. Upper bit line BL1 is shared by memory cells MC1 to MC3 arranged in the X direction.

In the present embodiment, the size of one memory cell is 8F² (F is the minimum fabrication dimension).

As shown in FIGS. 6 to 9, when the memory cells shown in FIGS. 1 to 4 are used to constitute a memory cell array, the source/drain regions of the select transistors functioning as lower bit lines bBL1 to bBL4 are shared by the adjacent memory cells (select transistors). Thus, memory cells MC1 to MC6 and the memory cell array 100 are reduced in size.

### (3) Operation

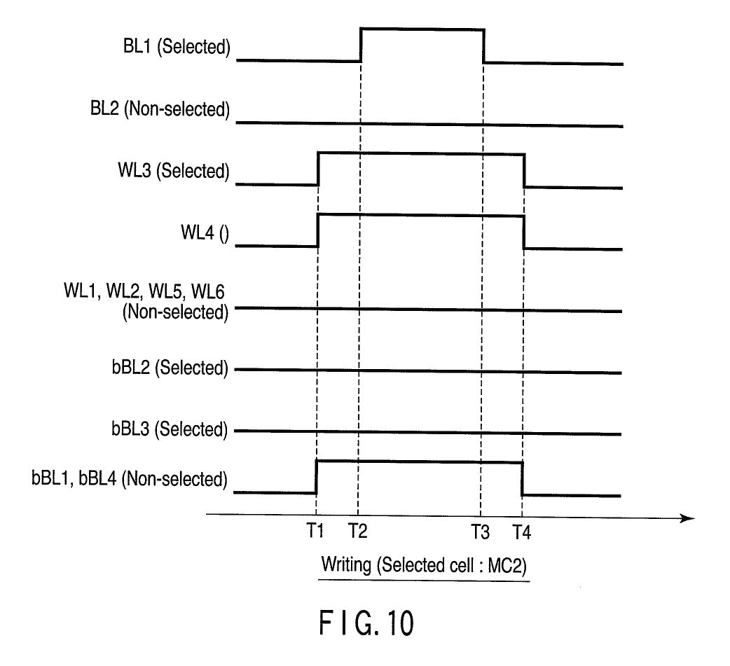

The operation of the resistance-change memory (MRAM) according to the present embodiment is described with FIGS. 10 to 12. The operation of the MRAM is described here properly using FIGS. 5 to 9 as well.

(a) Write Operation

First, the write operation of the MTJ element 10 performed by a spin transfer writing method is described with FIG. 5. In this explanation, the direction in which a current flows is opposite to the direction in which electrons move.

A parallel state (low-resistance state) in which the magnetization directions of the magnetization reference layer 12 and the magnetization free layer 14 are parallel is described. In this case, a current directed from the magnetization free layer 14 to the magnetization reference layer 12 is supplied. Electrons move from the magnetization reference layer 12 to the magnetization free layer 14. The majority of electrons which have passed through the magnetization reference layer 12 have a spin parallel to the magnetization direction of the magnetization reference layer 12. The spin angular momentum of the majority of electrons moves to the magnetization free layer 14, so that spin torque is applied to the magnetization free layer 14, and the magnetization direction of the magnetization free layer 14 is aligned parallel with the magnetization direction of the magnetization reference layer 12. The resistance of the MTJ element 10 in the case of this parallel arrangement is lowest. The case where the magnetization direction is parallel is defined as, for example, binary 0.

An antiparallel state (high-resistance state) in which the magnetization directions of the magnetization reference layer 12 and the magnetization free layer 14 are antiparallel is described. In this case, a current directed from the magnetization reference layer 12 to the magnetization free layer 14 is supplied. Electrons move from the magnetization free layer 14 to the magnetization reference layer 12. The majority of electrons which have been reflected by the magnetization reference layer 12 have a spin antiparallel to the magnetization direction of the magnetization reference layer 12. The spin angular momentum of the majority of electrons moves to the magnetization free layer 14, so that spin torque is applied to the magnetization free layer 14, and the magnetization direction of the magnetization free layer 14 is aligned antiparallel with the magnetization direction of the magnetization reference layer 12. The resistance of the MTJ element 10 in the case of this antiparallel arrangement is highest. The case where the magnetization direction is antiparallel is defined as, for example, binary 1.

The operation of writing to the MRAM shown in FIGS. 6 to 9 is described with FIG. 10. In addition, a write target selected cell is memory cell MC2 and referred to as a selected cell MC2. The memory cells other than the selected cell MC2 are referred to as non-selected cells MC1, MC3 to MC6.

First, at time T1, the potentials of the word lines (referred to as selected word lines) WL3, WL4 to which the selected cell MC2 is connected are changed from low (“L” level) to high (“H” level), and the selected word lines WL3, WL4 are activated.

In the present embodiment, one memory cell is connected to two word lines, so that word line WL3 and word line WL4 are activated. As a result, two select transistors ST1₂, ST2₂ constituting one selected cell MC2 are turned on.

The remaining word lines (referred to as non-selected word lines) WL1, WL2, WL5, WL6 connected to the non-selected cells MC1, MC3 to MC6 are kept at low potential. That is, the transistors in the non-selected cells are turned off.

Furthermore, lower bit lines (referred to as selected lower bit lines) bBL2, bBL3 connected to the selected cell MC2 are kept at low potential. In contrast, lower bit lines (referred to as non-selected lower bit lines) bBL1, bBL4 connected to the non-selected cells MC1, MC3 to MC6 are set at, for example, a potential opposite to the set potential of the selected lower bit lines bBL2, bBL3, that is, high potential. In addition, the lower bit line shared with the selected cell MC2 is made low even if connected to the non-selected cell.

Furthermore, at time T2, upper bit line (selected upper bit line) BL1 to which the selected cell MC2 is connected is made high. In contrast, the non-selected upper bit line BL2 is kept low.

Thus, a write current is supplied to the MTJ element 10₂ in the selected cell MC2 by a potential difference between upper bit line BL1 and lower bit lines bBL2, bBL3 in bit line pair BL1, bBL2, bBL3 to which the selected cell MC2 is connected. In addition, upper bit line BL1 is set at high potential (logical high), and lower bit lines bBL2, bBL3 are set at low potential (logical low), so that the write current flows from upper bit line BL1 to lower bit lines bBL2, bBL3. That is, electrons move from lower bit lines bBL2, bBL3 to upper bit line BL1.

In the present embodiment, two select transistors are provided for one MTJ element. At the time of writing, both of the two select transistors ST1₂, ST2₂ in the selected cell MC2 are turned on. Thus, a write current is supplied to one MTJ element 10₂ by the driving force (current transfer capability) of the two select transistors ST1₂, ST2₂. Therefore, in the present embodiment, a greater write current can be supplied to the MTJ element than in a memory cell (1Tr+1MTJ memory cell) in which one select cell is provided for one MTJ element.

In the present embodiment, a plurality of memory cells adjacent in the X direction in the memory cell array 100 are provided in one seamless (continuous) semiconductor region AA without being electrically separated by the element isolation regions. However, the non-selected word lines WL1, WL2, WL5, WL6 are made low, and the select transistors in the non-selected cells are turned off. Moreover, the non-selected lower bit lines bBL1, bBL4 which are not shared with the selected cell are set at the same potential as the selected upper bit line BL1, and the potential difference between the selected upper bit line and the non-selected lower bit lines is small.

Thus, the current (hereinafter referred to as a diverted current) supplied to the MTJ elements in the non-selected cells MC1, MC3 connected to the selected upper bit line BL1 is much smaller than an inversion threshold current. Therefore, even if the non-selected cells are provided in the same semiconductor region AA as the selected cell, no high current flows through the non-selected cells, and there is no erroneous writing to the non-selected cells.

A write current is passed through the MTJ element 10₂ in the selected cell MC2 during predetermined periods T2 to T3 to change the magnetization arrangement of the MTJ element 10₂ to a state corresponding to the data, and the potential of the upper bit line BL is then made low. Subsequently, at time T4, the non-selected lower bit lines bBL1, bBL4 are brought low. Then, the selected word lines WL3, WL4 are brought low, and the two select transistors ST1₂, ST2₂ in the selected cell MC2 are turned off.

As a result of the above-described operation, the operation of writing to the selected cell shown in FIG. 10 is finished in the present embodiment.

As described above, the magnetization directions of two magnetic layers of the MTJ element are changed to the parallel/antiparallel state in the MRAM, there is a need for an operation for passing the write current from the magnetization reference layer 12 to the magnetization free layer 14 and an operation for passing the write current from the magnetization free layer 14 to the magnetization reference layer 12. Thus, the potential of the upper bit line to which the selected cell is connected is set at a potential opposite to the potential of the lower bit line to which the selected cell is connected, so that a write current flowing in the opposite direction can be supplied to the MTJ element. That is, opposite to the set potentials in FIG. 10, the potentials of lower bit lines bBL2, bBL3 to which the selected cell MC2 is connected are made high, the potential of upper bit line BL1 to which the selected cell MC2 is connected is made low. As a result, a write current flowing in a direction opposite to that in the example shown in FIG. 10 is supplied to the MTJ element.

In this case as well, the two word lines WL3, WL4 connected to the selected cell MC2 are activated. Two select transistors in the selected cell are turned on. Moreover, the non-selected lower bit lines bBL1, bBL4 are set at the same potential (logical low) as the selected upper bit line BL1, and the non-selected upper bit line BL2 is set at the same potential logical high) as the selected lower bit lines bBL2, bBL3. This prevents the diverted current from passing through the MTJ element in the non-selected cell.

As described above, in the write operation shown in FIG. 10, both of the two select transistors constituting the selected memory cell are turned on, so that a large write current can be supplied to the MTJ element in the selected memory cell. Consequently, data can be normally written to the MTJ element.

(b) Read Operation

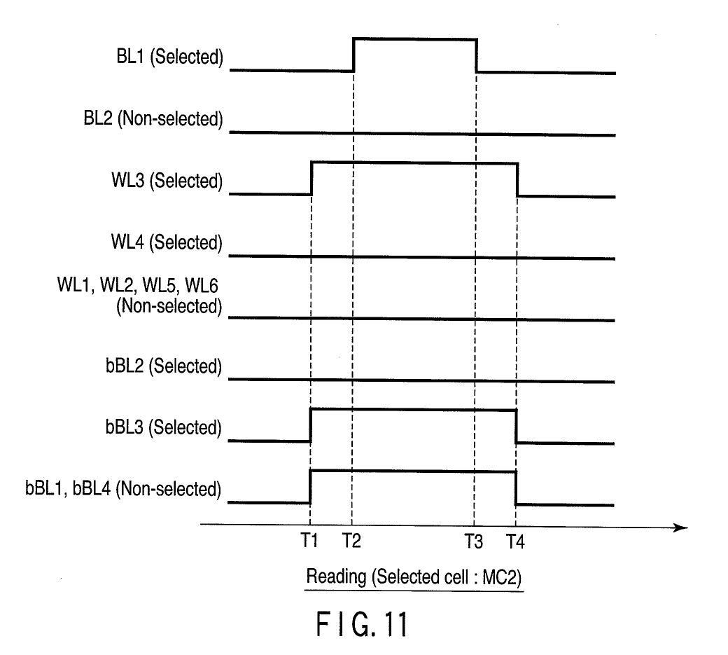

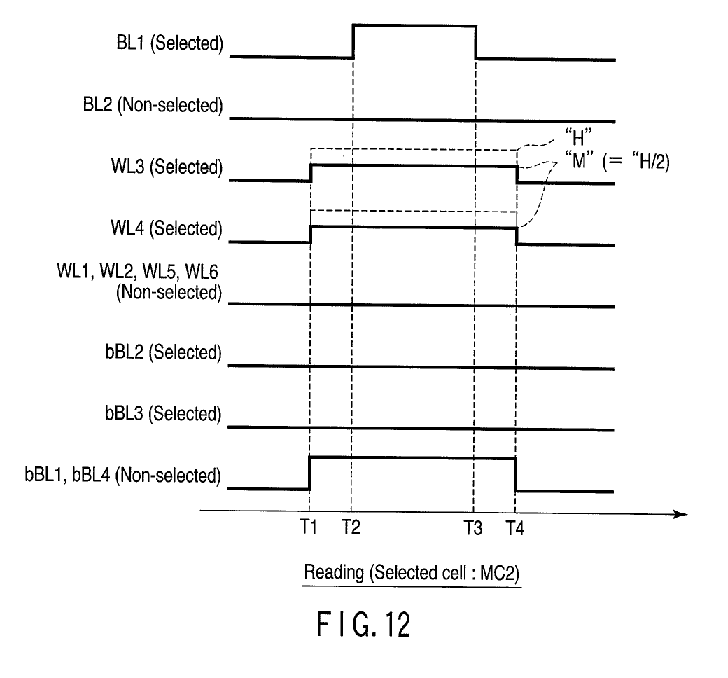

The read operation of the MRAM according to the present embodiment is described below with FIGS. 11 and 12.

In the MRAM, data is read by the supply of a read current to the MTJ element 10 shown in FIG. 5. A value defined as (R1−R0)/R0 is called the magnetoresistance ratio (MR ratio), wherein R0 is the resistance in a parallel state, and R1 is the resistance in an antiparallel state. The magnetoresistance ratio can take a value ranging from about several tens of percent to several hundreds of percent depending on the material that forms the MTJ element 10 and on a process condition. The magnitude of the variation of the read current attributed to this magnetoresistance ratio is detected to read information stored in the MTJ element 10. The read current passed through the MTJ element 10 during the read operation is set at, for example, a current sufficiently lower than a current at which the magnetization of the magnetization free layer (recording layer) is inverted by spin transfer.

FIG. 11 shows one example of the read operation of the MRAM according to the present embodiment. As in the write operation, the read target selected cell is memory cell MC2.

First, at time T1, the potential of one word line WL3 of the two word lines to which the selected cell MC2 is connected is made high, and the potential of the other word line WL4 is kept low. Thus, of the two select transistors in the selected cell MC2, select transistors ST2₂ connected to word line WL3 is turned on, and select transistors ST1₂ connected to word line WL4 is turned off.

Of the two lower bit lines bBL2, bBL3 connected to the selected cell, lower bit line bBL2 connected to select transistors ST2₂ in an on-state is made low. In contrast, the selected lower bit line bBL3 connected to select transistors ST2₁ in an off-state is made, for example, high. To prevent the diverted current from passing through the non-selected memory cell MC5 connected to the non-selected upper bit line BL2 and also connected to the selected word lines WL3, WL4, the potential of the selected lower bit line bBL3 may be made low.

The non-selected lower bit lines bBL1, bBL4 are set at, for example, the same potential (logical high) as the selected upper bit line BL1.

Furthermore, at time T2, the selected upper bit line BL1 is made high, and the non-selected upper bit line BL2 is made low. Thus, a read current is supplied to the MTJ element 10₂ in the selected cell MC2.

In the read operation shown in FIG. 11, of the two select transistors ST1₂, ST2₂ in the selected cell MC2, select transistors ST2₂ connected to word line WL3 is turned on, and select transistors ST1₂ connected to word line WL4 is turned off. Thus, select transistors ST2₂ alone contributes to the supply of the read current to the MTJ element 10₂. Therefore, the intensity of the read current supplied to the MTJ element 10₂ in the selected cell MC2 can be limited, and the value of the read current is much lower than that of the write current (magnetization inversion current). As a result, erroneous writing due to the read current is reduced.

Furthermore, the non-selected lower bit lines bBL1, bBL4 are set at the same potential (logical high) as the selected upper bit line BL1, and the select transistors connected to the non-selected word lines WL1, WL2, WL5, WL6 are off. As a result, the diverted current is hardly supplied to the non-selected cells MC1, MC3 connected to the selected upper bit line BL1.

A read current is supplied to the MTJ element 10₂ in the selected cell MC2 during predetermined periods T2 to T3, and data corresponding to the MR ratio of the MTJ element 10₂ is read. Then, the selected upper bit line BL1 is made low. Further, at time T4, the selected word lines WL3, WL4 and lower bit lines bBL1 to bBL4 are made low.

As a result of the above-described operation, the operation of reading from the selected cell shown in FIG. 11 is finished in the present embodiment.

In the case described here, the selected upper bit line BL1 is set at the high potential (logical high), and the selected lower bit line bBL2 is set at the low potential (logical low). However, it goes without saying that, contrary to the example shown in FIG. 11, the selected upper bit line BL1 may be set at the low potential and the selected lower bit line bBL2 may be set at the high potential to read from the selected cell. In this case, for example, the selected lower bit line bBL2 is set at the high potential, and the non-selected lower bit lines bBL1, bBL4 are set at the low potential.

FIG. 12 shows one example of the read operation of the MRAM according to the present embodiment. Here, the difference between this read operation and the read operation shown in FIG. 11 is described.

The major difference between this read operation and the read operation shown in FIG. 11 is that both of the two select transistors ST1₂, ST2₂ in the selected cell are driven. However, the potential applied to the selected word lines WL3, WL4 is set at middle potential between low and high. This middle potential is, for example, about half (H/2) that of the high potential applied to the word lines (select transistors).

The potential applied to the selected word lines WL3, WL4 is middle potential lower than high potential. Therefore, middle potential is applied to select transistors ST1₂, ST2₂ in the selected cell MC2 as the gate potential of the transistors, and select transistors ST1₂, ST2₂ are driven.

In the case where middle potential is used to drive the select transistors, the driving force of select transistors ST1₂, ST2₂ is lower than when high potential is used to drive the select transistors, and the current passing through the channels of select transistors ST1₂, ST2₂ is reduced. As a result, the intensity of the read current supplied to the MTJ element 10₂ in the selected cell MC2 can be much lower than that of the write current.

This makes it possible to prevent data from being erroneously written to the MTJ element 10₂ because of the supplied read current.

As described above, in the MRAM read operation shown in FIGS. 11 and 12, only one of the two select transistors constituting the selected memory cell is turned on, or the operation of the two select transistors is controlled to reduce the driving force, so that the intensity of the read current can be limited. This makes it possible to inhibit read disturb whereby data is written to the MTJ element because of the read current.

### (4) Specific Example

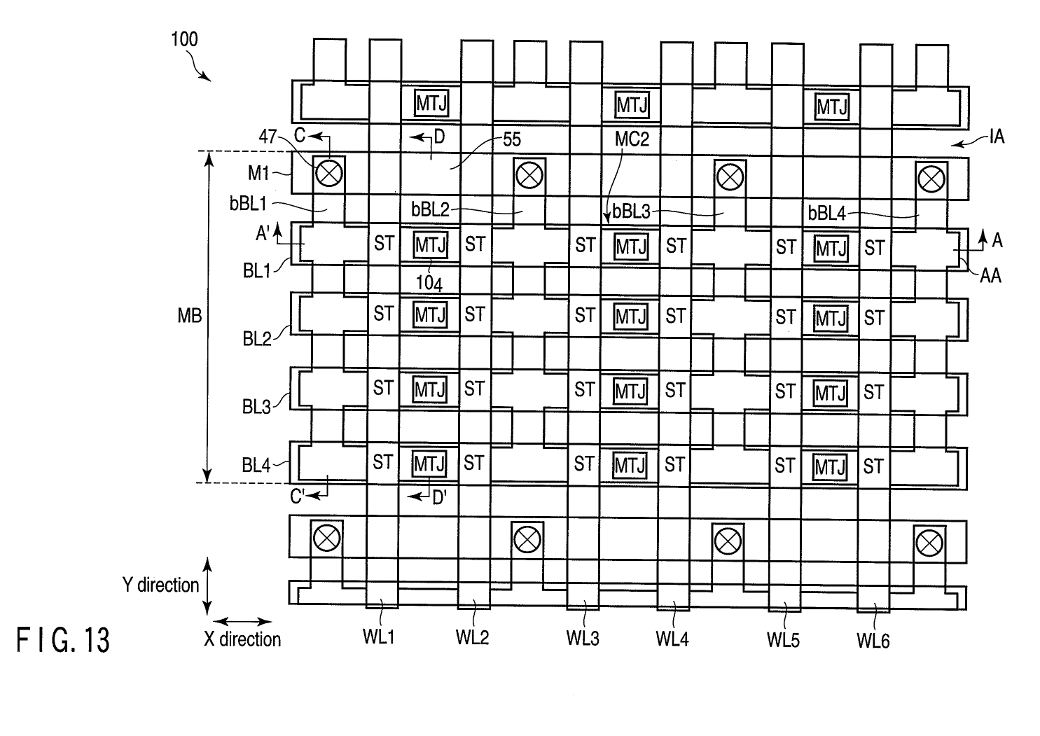

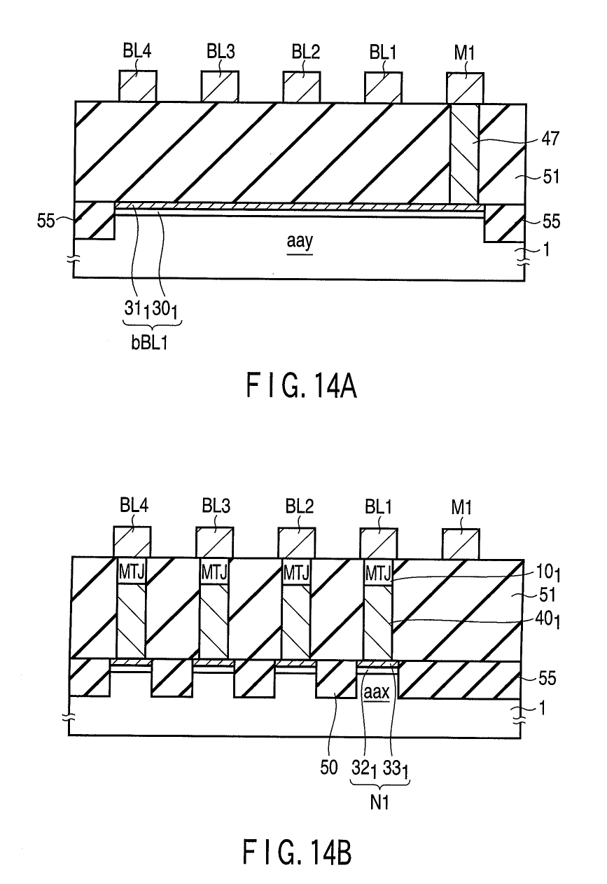

A more specific example of the resistance-change memory (MRAM) according to the embodiment of the present invention is described with FIGS. 13 to 15. FIG. 13 shows the planar structure of the memory cell array according to the present specific example. FIG. 14A shows a section taken along line C-C′ of FIGS. 13, and 14B shows a sectional view taken along line D-D′ of FIG. 13. The section taken along line A-A′ of FIG. 13 is substantially the same as that shown in FIG. 8 and is not described here.

When the memory cell array 100 is configured by using bit lines BL1 to BL4, bBL1 to bBL4 that extend in the directions intersecting with each other, the time for charging the bit lines tends to be increased during the operation of the MRAM.

Thus, in this example, four upper bit lines BL1 to BL4 extending in the X direction, for example, are treated as one group, and a plurality of memory cells respectively connected to the four bit lines are treated as one control unit (hereinafter referred to as a memory cell block MB). In addition, the number of upper bit lines included in one memory cell block is not exclusively four.

The plurality of memory cell blocks MB are adjacent in the Y direction, and arranged in the memory cell array 100. The memory cell blocks MB adjacent in the Y direction are electrically isolated by an element isolation region (hereinafter referred to as a block isolation region) IA. Further, in one memory cell block MB, lower bit lines bBL1 to bBL4 are disconnected on one end and the other in the Y direction from the adjacent memory cell block by the block isolation region IA. Thus, lower bit lines bBL1 to bBL4 are shared by a plurality of memory cells in one block MB but are not shared by the memory cell blocks MB adjacent in the Y direction.

In addition, word lines WL1 to WL6 extending in the same direction as lower bit lines bBL1 to bBL4 are provided, for example, over the block isolation region IA, and shared by a plurality of memory cell blocks.

As shown in FIGS. 13, 14A and 14B, a lead interconnect M1 is disposed at one end of the memory cell block in the Y direction. The lead interconnect M1 is provided at the same interconnect level as upper bit lines BL1 to BL4. The lead interconnect M1 is located above an insulating layer 55 embedded in the block isolation region IA.

Furthermore, the lead interconnect M1 has the common lower bit lines bBL1 to bBL4 in one memory cell block MB electrically connected thereto via contacts 47. The contacts 47 are disposed in the portions of lower bit lines bBL1 to bBL4 protruding in the Y direction.

The lead interconnect M1 is formed simultaneously with upper bit lines BL1 to BL4. Therefore, the manufacturing process is not increased even if the lead interconnect M1 is provided.

Moreover, the same material (e.g., a metal) as the material for upper bit lines BL1 to BL4 is used for the lead interconnect M1. Then, the memory cells provided in the memory cell array are isolated block by block as described above, so that the source/drain regions (silicide layer/impurity diffusion layer) using as lower bit lines bBL1 to bBL4 are decreased in length in the Y direction. This makes it possible to reduce the resistances and parasitic capacitances of lower bit lines bBL1 to bBL4.

Thus, in the specific example shown in FIGS. 13, 14A and 14B, the memory cell block MB having a predetermined number of upper bit lines as a unit is set in the memory cell array 100, thereby limiting the number of upper bit lines and the number of memory cells that share the lower bit lines and also limiting the interconnect length of the lower bit lines. This makes it possible to inhibit the increase of the time for charging the bit lines, in particular, the lower bit lines (source/drain regions) in the memory cell array.

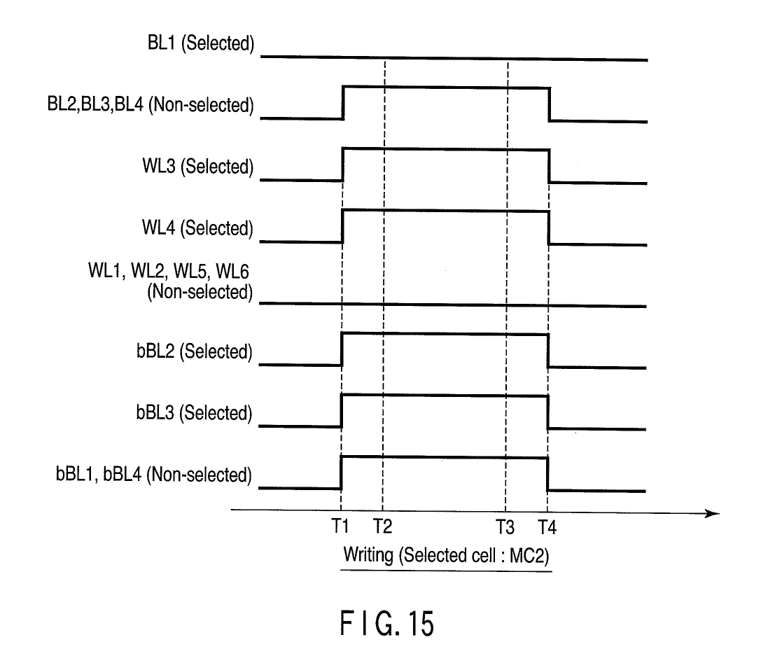

The operation of the MRAM shown in FIGS. 13, 14A and 14B is described below with FIG. 15.

In the configuration shown in FIGS. 13, 14A and 14B, one lead interconnect M1 is connected to the common lower bit lines bBL1 to bBL4 in the memory cell block MB. Therefore, during the write or read operation, the same potential is applied to control the potentials of lower bit lines bBL1 to bBL4.

In this case, during the operation of the MRAM, the potentials of upper bit lines BL1 to BL4 to which the non-selected cells are connected are set at the same potentials as the potential of lower bit lines bBL1 to bBL4 connected to the non-selected cells. As a result, the potential difference applied to the bit line pair to which the non-selected cells are connected is set at substantially zero, and no current is passed through the non-selected cells.

For example, when the write operation is performed for memory cell MC2 as the selected cell in the same manner as described above, two selected lower bit lines bBL2, bBL3 are set at high potential (logical high), and the selected upper bit line BL1 is set at low potential (logical low), as shown in FIG. 15. In this case, the lower bit lines connected to the same common interconnect M1 have about the same potential. Therefore, lower bit lines bBL1, bBL4 which are non-selected lower bit lines also have the same potential as the selected lower bit lines bBL2, bBL3.

In the present example, the same potential as that for of the lower bit lines, here, high potential (logical high) is applied to the non-selected upper bit lines BL2 to BL4. Thus, the potential difference applied to the bit line pair is small, so that the diverted current is hardly passed through the non-selected cells connected to the same lower bit lines bBL2, bBL3 as the selected cell MC2.

Furthermore, in this case as well, the memory cells adjacent in the X direction can be electrically isolated by the cutoff of the select transistors. Thus, no diverted current is passed through the memory cells adjacent in the X direction of the selected cell MC2.

Moreover, in the example shown in FIGS. 11, 12 and 15, a potential (here, high) is applied to the non-selected upper bit lines BL2 to BL4, for example, by the same timing (time T1) as the application of the potential to the selected word lines WL3, WL4. The timing whereby the potential level of the non-selected upper bit lines BL2 to BL4 is made low is also the same as the timing (time T4) whereby the potential level of the selected word lines WL3, WL4 is made low. Thus, the potential application to the non-selected upper/lower bit lines precedes the potential application to the selected upper/lower bit lines, thereby making it possible to prevent the operation of the selected cell from deteriorating because of, for example, noise caused by the potential application to the non-selected bit lines.

In the case where the upper bit line to which the selected cell is connected is set at high potential and the lower bit line to which the selected cell is connected is set at low potential, the upper bit line to which the non-selected cell is connected may be set at low potential.

Furthermore, in the read operation for the selected cell, the non-selected upper bit lines are set at the same potential as the selected lower bit lines as in the write operation, so that no diverted current is passed through the non-selected cells connected to the same lower bit line to which the selected cell is connected.

In the write operation and read operation shown in FIGS. 10 to 12, the potential of the non-selected upper bit line BL2 may be set at the same potential as that of the selected lower bit lines bBL2, bBL3 to inhibit the generation of a diverted current in the non-selected cell which is connected to the selected lower bit lines bBL2, bBL3 and the non-selected upper bit line BL2.

Still further, in the memory cell array shown in FIGS. 13 to 14B, a middle potential may be applied to the selected word line during the read operation for the selected cell to control the operation of the transistors in the selected cell.

As described above, the plurality of lower bit lines bBL1 to bBL4 are connected to the same common interconnect, so that the operation of the MRAM is not deteriorated even if the same potential is applied to these lower bit lines. It goes without saying that one lead interconnect may be connected to each of lower bit lines bBL1 to bBL4 for the sake of stable operation.

### (5) Summary

As has been described with FIGS. 1 to 9 in connection with the resistance-change memory, for example, the MRAM according to the embodiment of the present invention, bit lines BL1, bBL1, bBL2 to form a bit line pair extend in the directions intersecting with each other. In the present embodiment, the bit line pair is constituted of three bit lines BL1, bBL1, bBL2, and is formed at a different interconnect level. One bit line (upper bit line) BL1 extends in a first direction (Y direction) and is provided above the substrate 1. Two bit lines (lower bit lines) bBL1, bBL2 extend in a second direction (X direction) and are provided in the substrate 1. In the memory according to the present embodiment, two lower bit lines bBL1, bBL2 pair with one upper bit line BL1.

In one memory cell MC1, two select transistors ST1, ST2 are connected to one MTJ element (resistance-change storage element) 10. Upper bit line BL1 is connected to one end of the MTJ element 10, and the other end of the MTJ element 10 is connected to one end (source/drain region) of the current path shared by the two select transistors ST1, ST2. Lower bit line bBL1 is connected to the other end of the current path of one select transistor ST1, and this lower bit line bBL1 is, for example, the source/drain region of select transistor ST1. Similarly, the other end of the current path of the other select transistor ST2 is the source/drain region of the transistor, and functions as lower bit line bBL2.

Thus, in the resistance-change memory according to the present embodiment, the source/drain regions of select transistors ST1, ST2 are used as bit lines bBL1, bBL2, so that the process of forming the interconnect layers is reduced as compared with the case where the bit line pair is formed by using an interconnect made of a metal. Moreover, in the memory according to the present embodiment, there is no need to use a metal for the lower bit lines, and the manufacturing costs can therefore be reduced.

Furthermore, when the memory cell array is configured by the memory cells described above, the adjacent memory cells are electrically isolated by the cutoff of the select transistors included in the memory cell and by controlling the potential of the lower bit line (the source/drain region of the select transistor) shared by the adjacent memory cells, without using any element isolation region in which an insulating layer is embedded.

This makes it possible to reduce the space reserved to dispose the element isolation region and to reserve an area to dispose the memory cell instead of the element isolation region. Further, the source/drain region of the select transistor functioning as the lower bit line is shared by the select transistors of the memory cells adjacent in the X direction, which enables a reduction in cell size. Therefore, in the resistance-change memory according to the present embodiment, the storage density of the memory cell array can be improved, which thus contributes to the reduction of the manufacturing costs of the memory.

Still further, in the present embodiment, two select transistors ST1, ST2 are provided for one MTJ element 10 in one memory cell MC1.

Thus, as in the write operation described with FIG. 10, the driving force for the two select transistors ST1, ST2 are ensured, and the two select transistors contribute to the supply of the write current to the MTJ element 10. As a result, in contrast with the 1Tr+1MTJ memory cell, the write current can be greater, and a write current that is high enough to change the magnetization arrangement of the MTJ element by spin transfer can supplied to the MTJ element. This makes it possible to prevent predetermined data from being unsuccessfully written to the MTJ element because of the insufficient write current, and to normally write the data.

As shown in FIGS. 11 and 12, one of the select transistors is turned off or the two select transistors are driven by a low gate potential in the read operation, so that the read current can be smaller. Thus, a high read current is not supplied to the MTJ element, and the read disturb can be reduced.

Further yet, in a memory in which a plurality of bit lines constituting a bit line pair extend in intersecting directions, high-speed charging of the bit lines has heretofore been impossible.

However, in the memory according to the present embodiment, the driving force of the two select transistors contributes to the current supply. Moreover, as has been shown in FIGS. 13, 14A and 14B, in the memory according to the present embodiment, for example, a plurality of memory cells respectively connected to a predetermined number of (e.g., four) upper bit lines are set as one unit (memory cell block), and the number of upper bit lines sharing the lower bit lines and the interconnect length of the lower bit lines are thus limited. Thus, the time required to charge the bit lines is reduced, and the memory can perform high-speed operation even in the case of a memory cell array having a configuration in which a plurality of bit lines to make a pair extend in the directions intersecting with each other.

Therefore, according to the resistance-change memory (MRAM) in the embodiment of the present invention, manufacturing costs can be reduced, and operating characteristics can be improved.

### MODIFICATION

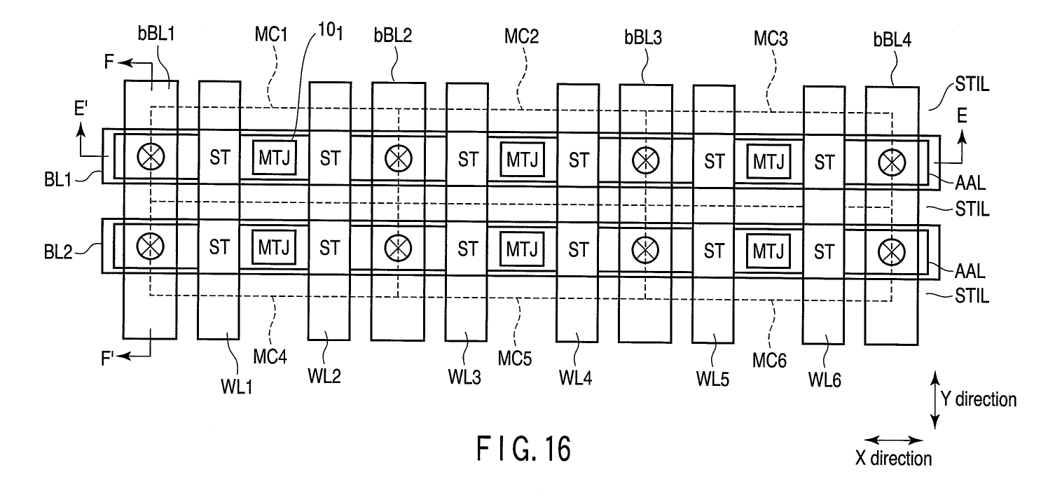

A modification of the resistance-change memory (MRAM) according to the embodiment of the present invention is described with FIGS. 16 to 18. It is to be noted that the same components as the components described above are provided with the same reference numbers and are repeatedly described when necessary.

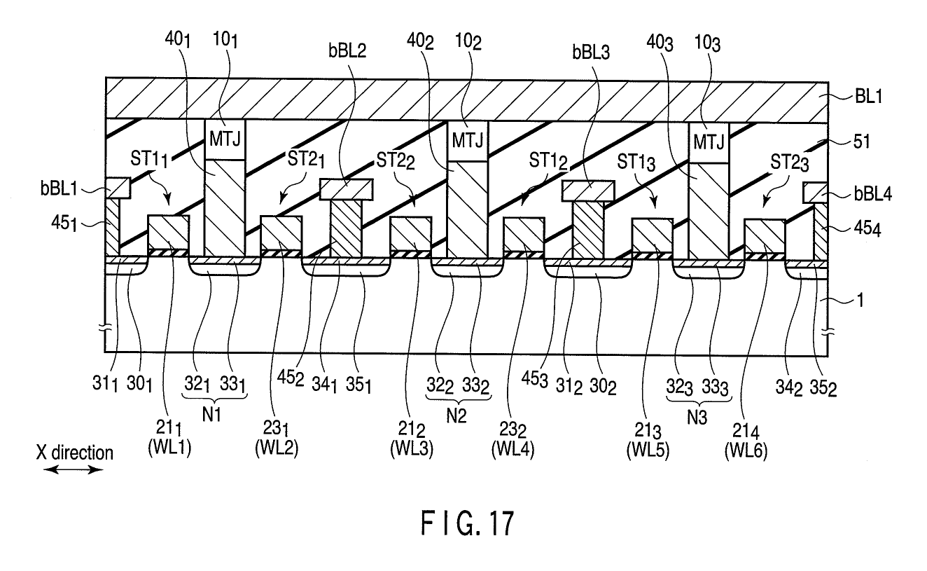

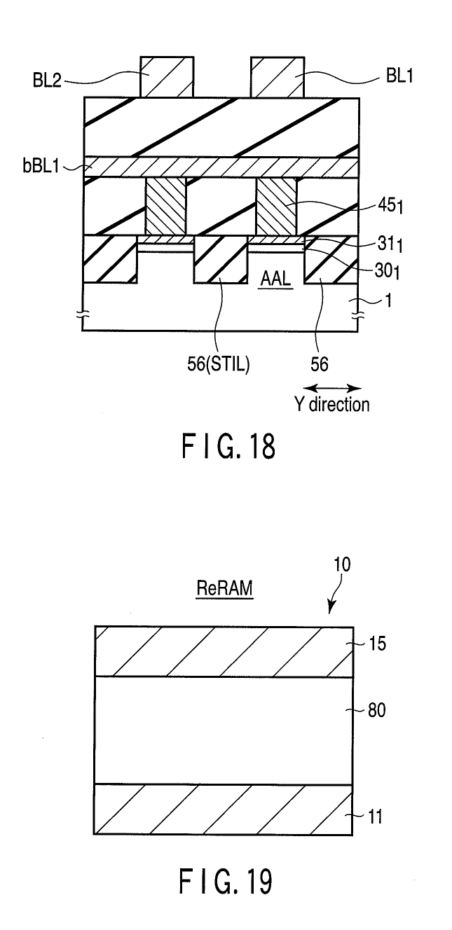

FIG. 16 shows the planar structure of a memory cell array according to the present modification. FIG. 17 shows a section taken along line E-E′ of FIG. 16, and FIG. 18 shows a section taken along line F-F′ of FIG. 16.

In the present modification, as shown in FIGS. 16 to 18, an interconnect made of a conductor (e.g., a metal) is formed as a lower bit line at the interconnect level between the surface of a substrate 1 and an upper bit line BL1, without using, as lower bit line bBL, a source/drain region extending in the Y direction. Thus, lower bit lines bBL1 to bBL4 extending in a direction intersecting with the upper bit line are made.

The surface region of the substrate (memory cell array) 1 includes a semiconductor region AAL having a striped (linear) planar shape extending in the X direction, and an element isolation region STIL having a striped planar shape extending in the X direction. In the surface of the substrate 1, one semiconductor region AAL is interposed between two element isolation regions STIL. The striped semiconductor region AAL extends from one end of the memory cell array to the other in the X direction.

In the configuration of the memory cell array shown in the present modification, two metal interconnects are used to form upper bit lines BL1, BL2 and lower bit lines bBL1 to bBL4, and the number of manufacturing steps and manufacturing costs are increased.

Instead, the surface region of the substrate can be constituted of the striped semiconductor region AAL and the striped element isolation regions STIL. Therefore, the surface of the substrate 1 can be easily processed.

Furthermore, when the planar shape of the element isolation region STI is quadrangular as shown in FIG. 7, the corners of the quadrangular shape may be missing or rounded depending on the conditions of exposure or etching. As a result, the shape of the source/drain region (lower bit line) is distorted, and an electric field at the end of the gate length direction (X direction) is distorted, so that the operating characteristics of the memory cell deteriorate. Moreover, since faults in the shape of the element isolation region are caused in a nonuniform manner, there is a characteristic variation among the memory cells provided in the memory cell array 100.

In the MRAM according to the present modification, the striped element isolation regions STIL can be formed. Thus, deterioration in the characteristics of the memory cell due to the shape distortion of the element isolation regions is inhibited, and the characteristic variation among the memory cells can be reduced.

Moreover, the lower bit line made of a metal is used, so that interconnect resistance can be reduced, and the time required to charge the bit line pair can be reduced. As a result, there is no need to disconnect the lower bit line to reduce parasitic resistance and parasitic capacitance in contrast with the lower bit line formed of the silicide layer/impurity layer. Moreover, there is no need to provide the element isolation region for the disconnection. Therefore, the storage capacity and storage density of the memory cell array can be improved.

In addition, the operation shown in FIGS. 10 to 12 and FIG. 15 can be applied to the operation of the MRAM shown in FIGS. 16 to 18.

[Application]

As described above, various memories other than the MRAM can be used as the resistance-change memory according to the embodiment of the present invention. Such memories also provide effects similar to the effects of the above-described MRAM. A ReRAM and a PCRAM are described below as alternative examples of the resistance-change memory.

(a) ReRAM

FIG. 19 is a schematic diagram showing the configuration of a resistance-change storage element 10 used in the ReRAM. The resistance-change storage element (variable resistance element) 10 comprises a lower electrode 11, an upper electrode 15, and a recording layer 80 interposed therebetween.

The recording layer 80 is made of a transition metal oxide such as a perovskite-like metal oxide or a binary metal oxide. The perovskite-like metal oxide includes, for example, PCMO (Pr_{0.7}Ca_{0.3}MnO₃), Nb-added SrTi(Zr)O₃ and Cr-added SrTi(Zr)O₃. The binary metal oxide includes, for example, NiO, TiO₂ and Cu₂O.

The resistance-change storage element 10 includes an element of an operation mode called a bipolar type and an element of an operation mode called a unipolar type. The bipolar element 10 changes its resistance in accordance with the change of the polarity of a voltage applied thereto. The unipolar element 10 changes its resistance in accordance with the change of the absolute value or pulse width of a voltage applied thereto. Thus, the resistance-change storage element 10 is set in a low-resistance state or a high-resistance state by the control of the applied voltage. Whether the element is bipolar or unipolar depends on the material of the recording layer 80 to be selected.

For example, when the bipolar resistance-change storage element 10 is used, a voltage for shifting the resistance-change storage element 10 from the high-resistance state (reset state) to the low-resistance state (set state) is a set voltage Vset, while a voltage for shifting the variable resistive element 10 from the low-resistance state (set state) to the high-resistance state (reset state) is a reset voltage Vreset.

The set voltage Vset is set to a positive bias for applying a positive voltage to the upper electrode 15 as opposed to the lower electrode 11, while the reset voltage Vreset is set to a negative bias for applying a negative voltage to the upper electrode 15 as opposed to the lower electrode 11. Further, the low-resistance state and the high-resistance state are matched with binary 0 and binary 1, respectively, such that the resistance-change storage element 10 can store one-bit data.

For reading, a sufficiently low read voltage which is about 1/1000 to ¼ of the reset voltage Vreset is applied to the resistance-change storage element 10. Then, a current flowing through the resistance-change storage element 10 of the ReRAM at the moment is detected such that data can be read.

(b) (PCRAM)

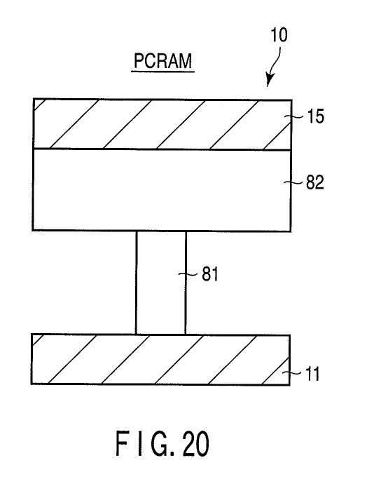

FIG. 20 is a schematic diagram showing the configuration of the resistance-change storage element 10 used in the PCRAM. The resistance-change storage element 10 has a lower electrode 11, a heater layer 81, a recording layer 82 and an upper electrode 15 that are stacked in order.

The recording layer 82 is made of a phase-change material, and is set to a crystalline state or noncrystalline state by heat generated during writing. The material of the recording layer 82 includes chalcogen compounds such as Ge—Sb—Te, In—Sb—Te, Ag—In—Sb—Te and Ge—Sn—Te. These materials are preferable in ensuring high-velocity switching characteristics, repeated recording stability and high reliability.

The heater layer 81 is in contact with the bottom surface of the recording layer 82. The area of contact of the heater layer 81 with the recording layer 82 is preferably smaller than the area of the bottom surface of the recording layer 82. The purpose is to decrease a write current or voltage by reducing the contact part between the heater layer 81 and the recording layer 82 to reduce a heated part. The heater layer 81 is made of a conductive material, and is preferably made of, for example, a material selected from the group consisting of TiN, TiAlN, TiBN, TiSiN, TaN, TaAlN, TaBN, TaSiN, WN, WAlN, WBN, WSiN, ZrN, ZrAlN, ZrBN, ZrSiN, MoN, Al, Al—Cu, Al—Cu—Si, WSi, Ti, Ti—W and Cu. Moreover, the heater layer 81 may be made of the same material as the lower electrode 11 described later.

The area of the lower electrode 11 is greater than the area of the heater layer 81. The upper electrode 15 has, for example, the same planar shape as the recording layer 82. The material of the lower electrode 11 and the upper electrode 15 includes a high melting point metal such as Ta, Mo or W.

The heating temperature of the recording layer 82 changes by controlling the intensity of a current pulse applied thereto or the width of the current pulse, such that the recording layer 82 changes to the crystalline state or noncrystalline state. Specifically, in writing, a voltage or current is applied across the lower electrode 11 and the upper electrode 15, and a current is passed to the lower electrode 11 from the upper electrode 15 via the recording layer 82 and the heater layer 81. If the recording layer 82 is heated to near the melting point, the recording layer 82 changes to a noncrystalline phase (high-resistive phase), and remains in the noncrystalline state even when the application of the voltage or current is stopped.

In contrast, a voltage or current is applied across the lower electrode 11 and the upper electrode 15. If the recording layer 82 is heated to near a temperature suitable for crystallization, the recording layer 82 changes to a crystalline phase (low-resistive phase), and remains in the crystalline state even when the application of the voltage or current is stopped. When the recording layer 82 is changed to the crystalline state, the set intensity of the current pulse applied to the recording layer 82 is lower and the set width of the current pulse is greater than, for example, when the recording layer 82 is changed to the noncrystalline state. Thus, a voltage or current is applied across the lower electrode 11 and the upper electrode 15 to heat the recording layer 82, such that the resistance of the recording layer 82 can be changed.

Whether the recording layer 82 is in the crystalline phase or the noncrystalline phase can be known by applying, across the lower electrode 11 and the upper electrode 15, such a low voltage or low current that does not cause the recording layer 82 to be crystalline or noncrystalline and reading the voltage or current across the lower electrode 11 and the upper electrode 15. Thus, the low-resistance state and the high-resistance state are matched with binary 0 and binary 1, respectively, such that one-bit data can be read from the resistance-change storage element 10 of the PCRAM.

[Others]

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A resistance-change memory comprising:
a first bit line extending in a first direction;
second and third bit lines extending in a second direction intersecting with the first direction;
first and second word lines extending in the second direction;
a first select transistor comprising a control terminal connected to the first word line and a first current path, the first current path comprising a first end connected to the second bit line;
a second select transistor comprising a control terminal connected to the second word line and a second current path, the second current path comprising a first end connected to the third bit line and a second end which is a common node with a second end of the first current path of the first select transistor; and
a resistance-change storage element comprising a first end connected to the first bit line and a second end connected to the common node, configured to change resistance in accordance with data to be stored.

2. The resistance-change memory of claim 1, wherein
during a write operation,
the first and second select transistors are turned on, and the first bit line is set at a potential different from a potential of the second and third bit lines if the resistance-change storage element is a target for writing, and
the potential of at least one of the second and third bit lines is set at the same potential as the potential of the first bit line if the resistance-change storage element is not a target for writing.

3. The resistance-change memory of claim 1, wherein
during a read operation,
the first select transistor is turned on, the second select transistor is turned off, and the first bit line is set at a potential different from the potential of the second and third bit lines if the resistance-change storage element is a target for reading, and
the potential of at least one of the second and third bit lines is set at the same potential as the potential of the first bit line if the resistance-change storage element is not a target for reading.

4. The resistance-change memory of claim 1, wherein
during a read operation,
the first bit line is set to a first potential of a first level, the second and third bit lines are set to a second potential of a second level, the first and second word lines are set to a third potential of a level between the first level and the second level, and the third potential is configured to drive the first and second select transistors, if the resistance-change storage element is a target for reading,
the potential of at least one of the second and third bit lines is set at the same potential as the potential of the first bit line if the resistance-change storage element is not a target for reading.

5. The resistance-change memory of claim 1, wherein
the resistance-change storage element is a magnetoresistive effect element.

6. A resistance-change memory comprising:
a first bit line above a substrate and extending in a first direction;
a first select transistor which comprises a first source and drain region as a second bit line in the substrate and extending in a second direction intersecting with the first direction, a second source and drain region in the substrate, and a first gate electrode as a first word line on the substrate between the first and second source and drain regions via a gate insulating film;
a second select transistor comprising the second source and drain region shared with the first select transistor, a third source and drain region as a third bit line in the substrate and extending in the second direction, and a second gate electrode as a second word line on the substrate between the second and third source and drain regions via a gate insulating film; and
a first resistance-change storage element comprising a first terminal connected to the first bit line and a second terminal connected to the second source and drain region under the first bit line, the first resistance-change storage element configured to reversibly change resistance in accordance with data to be stored.

7. The resistance-change memory of claim 6, wherein
during a write operation,
the first and second select transistors are turned on, and the first bit line is set at a potential different from a potential of the second and third bit lines if the resistance-change storage element is a target for writing, and
the potential of at least one of the second and third bit lines is set at the same potential as the potential of the first bit line if the resistance-change storage element is not a target for writing.

8. The resistance-change memory of claim 6, wherein
during a read operation,
the first select transistor is turned on, the second select transistor is turned off, and the first bit line is set at a potential different from the potential of the second and third bit lines if the resistance-change storage element is a target for reading, and
the potential of at least one of the second and third bit lines is set at the same potential as the potential of the first bit line if the resistance-change storage element is not a target for reading.

9. The resistance-change memory of claim 6, wherein
during a read operation,
the first bit line is set to a first potential of a first level, the second and third bit lines are set to a second potential of a second level, the first and second word lines are set to a third potential of a level between the first level and the second level, and the third potential is configured to drive the first and second select transistors, if the resistance-change storage element is a target for reading,
the potential of at least one of the second and third bit lines is set at the same potential as the potential of the first bit line if the resistance-change storage element is not a target for reading.

10. The resistance-change memory of claim 6, wherein
the first bit line comprises metal, and the second and third bit lines are nonmetallic conductors.

11. The resistance-change memory of claim 6, wherein
the resistance-change storage element is a magnetoresistive effect element.

12. The resistance-change memory of claim 6, further comprising:
a third select transistor comprising the third source and drain region shared with the second select transistor, a fourth source and drain region in the substrate, and a third gate electrode as a third word line on the substrate between the third and fourth source and drain regions via a gate insulating film;
a fourth select transistor comprising the fourth source and drain region shared with the third select transistor, a fifth source and drain region as a fourth bit line in the substrate and extending in the second direction, and a fourth gate electrode as a fourth word line on the substrate between the fourth and fifth source and drain regions via a gate insulating film; and
a second resistance-change storage element comprising a third terminal connected to the first bit line and a fourth terminal connected to the fourth source and drain region and under the first bit line, the second resistance-change storage element configured to reversibly change resistance in accordance with data to be stored.

13. The resistance-change memory of claim 12, wherein
the first, second, third and fourth select transistors are on a semiconductor region extending in the first direction.

14. The resistance-change memory of claim 6, further comprising:
a fourth bit line above the substrate, extending in the first direction, and adjacent to the first bit line in the second direction;
a third select transistor adjacent to the first select transistor in the second direction, the third select transistor comprising a fourth source and drain region as a fifth bit line in the substrate and extending in the second direction, a fifth source and drain region in the substrate, and a third gate electrode as the first word line on the substrate between the fourth and fifth source and drain regions via a gate insulating film;
a fourth select transistor adjacent to the second select transistor in the second direction, the fourth select transistor comprising the fifth source and drain region shared with the third select transistor, a sixth source and drain region as a sixth bit line in the substrate and extending in the second direction, and a fourth gate electrode as the second word line on the substrate between the fifth and sixth source and drain regions via a gate insulating film; and
a second resistance-change storage element comprising a fourth terminal connected to the fourth bit line and a fifth terminal connected to the fifth source and drain region and under the fourth bit line, the second resistance-change storage element configured to reversibly change resistance in accordance with data to be stored.

15. The resistance-change memory of claim 14, wherein
the first and fourth source and drain regions are a region extending in the second direction,
the third and sixth source and drain regions are a region extending in the second direction.

16. The resistance-change memory of claim 14, wherein
the forth and sixth source and drain regions are electrically isolated from the first and third source and drain regions by an insulating film in the substrate.

17. A resistance-change memory comprising:
a first bit line above a substrate and extending in a first direction;
an active region in a memory cell array in the substrate, extending from a first end of the memory cell array to a second end of the memory cell array in the first direction, and between two element isolation insulating films in the substrate in a second direction intersecting with the first direction;
a first select transistor comprising a first source and drain region in the active region, a second source and drain region in the active region, and a first gate electrode on the substrate between the first and second source and drain regions via a gate insulating film;
a second select transistor comprising the second source and drain region shared with the first select transistor, a third source and drain region in the active region, and a second gate electrode on the substrate between the second and third source and drain regions via a gate insulating film;
a resistance-change storage element comprising a first end connected to the first bit line and a second end connected to the second source and drain region and under the first bit line, the resistance-change storage element is configured to reversibly change resistance in accordance with data to be stored;
a second bit line between the first bit line and the first source and drain region, connected to the first source and drain region and extending in a second direction intersecting with the first direction; and
a third bit line between the first bit line and the third source and drain region, connected to the third source and drain region and extending in the second direction.

18. The resistance-change memory of claim 17, wherein
during a write operation,
the first and second select transistors are turned on, and the first bit line is set at a potential different from a potential of the second and third bit lines if the resistance-change storage element is a target for writing, and
the potential of at least one of the second and third bit lines is set at the same potential as the potential of the first bit line if the resistance-change storage element is not a target for writing.

19. The resistance-change memory of claim 17, wherein
during a read operation,
the first select transistor is turned on, the second select transistor is turned off, and the first bit line is set at a potential different from the potential of the second and third bit lines if the resistance-change storage element is a target for reading, and
the potential of at least one of the second and third bit lines is set at the same potential as the potential of the first bit line if the resistance-change storage element is not a target for reading.

20. The resistance-change memory of claim 17, wherein
during a read operation,
the first bit line is set to a first potential of a first level, the second and third bit lines are set to a second potential of a second level, the first and second word lines are set to a third potential of a level between the first level and the second level, and the third potential is configured to drive the first and second select transistors if the resistance-change storage element is a target for reading,
the potential of at least one of the second and third bit lines is set at the same potential as that of the first bit line if the resistance-change storage element is not a target for reading.
